(19) United States
(12) Patent Application Publication
(10) Pub. No.: US 2008/0311864 A1
(43) Pub. Date: Dec. 18, 2008

(54) Determining the Current Value of Transmission Power of a Radio Telecommunication Device

(75) Inventor: Mark Wallis, Mouans Sartoux (FR)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: KONINKLIJKE PHILIPS ELECTRONICS N.V., Eindhoven (NL)

(21) Appl. No.: 11/572,802

(22) PCT Filed: Jul. 19, 2005
(86) PCT No.: PCT/IB2005/052401

§ 371 Date: Jan. 26, 2007

(30) Foreign Application Priority Data
Jul. 28, 2004 (EP) 04300483.7

(51) Int. Cl. H04B 7/005; H03G 3/30

(52) U.S. Cl. 455/115.1

(57) ABSTRACT

A radio telecommunication device able to determine the current value of the transmission power comprises: a capturing unit to measure at least one operating condition of an amplifier influencing the value of the transmission power corresponding to a given gain setting value, and a determining module (46) adapted to establish the current value of the transmission power from a current gain setting value of the amplifier and the at least one measured operating condition.

### FIELD OF THE INVENTION

The present invention relates to the determination of the current value of the transmission power of a radio telecommunication device.

### BACKGROUND OF THE INVENTION

A CDMA (Code Division Multiple Access) radio telephone system includes a network base station and more than one mobile user stations. Hereinafter the user station is referred to as the radio telecommunication device. When the radio telecommunication device is in communication over a shared radio frequency interface, there is a need to control the radio frequency transmission power of each telecommunication device. This primarily ensures an acceptable signal quality on all communication channels of all users, while the power consumption of each telecommunication device is minimized. Thus, the radio telecommunication device comprises an amplifier having a tunable gain for setting a transmission power of a radio communication according to a gain setting value.

An example of such a conventional telecommunication device is described in US 2002/0176513.

A standard like the 3GPP standard (Third Generation Partnership Project) for UMTS (Universal Mobile Telecommunication System) specifies for each telecommunication device:
a first tolerance on the transmission power change, and
a second tolerance on the maximum transmission power.

The second tolerance is specified according to an absolute maximum transmission power limit. For example, the maximum transmission power limit for a class 3 telecommunication device is 24 dBm (decibel referenced as 1 milliwatt) and the tolerance is in the range of −3 dB to +1 dB.

However, due to non-linearities and errors in the amplifier, a nominal gain set by a processor may not always correspond to the desired transmission power. This error may be compounded by the effect of temperature changes, power supply voltage changes, frequency changes and other operating conditions of the amplifier. As a result, the second tolerance, when it approaches the maximum transmission power limit, is harder to achieve. Thus, many designs for radio telecommunication devices require direct measurements of the radio frequency transmission power.

### SUMMARY OF THE INVENTION

Accordingly, it is an object of the invention to provide a radio telecommunication device that does not need a radio frequency transmission power detector to control the transmission power according to specified tolerances.

With the foregoing and other objects in view, there is provided, in accordance with the invention, a radio telecommunication device wherein the telecommunication device comprises:
an amplifier having a tunable gain for setting a transmission power of a radio communication according to a gain setting value,
a capturing unit to measure at least one operating condition of the amplifier influencing the value of the transmission power corresponding to a given gain setting value, and
a determining module adapted to establish the current value of the transmission power from the current gain setting value of the amplifier and the at least one measured operating condition.

The above radio telecommunication device takes into consideration at least one measured operating condition of the amplifier to establish the current value of the transmission power without measuring it. Therefore, the device establishes a value for the transmission power with more accuracy than a conventional telecommunication device, so that the measurement of the actual transmission power may be omitted.

The radiotelecommunication device according to the invention, wherein
it comprises a memory storing gain setting values and a first and a second expected transmission power value associated to each stored gain setting value, and
the determining module is adapted to select either one of the first and second expected transmission power values according to the at least one measured condition to establish the current value of the transmission power,
   facilitates the determination of the transmission power value according to the measured operating condition of the amplifier.

The radiotelecommunication device according to the invention, wherein each stored gain setting value is an integer value, simplifies the implementation of the gain control.

The radiotelecommunication device according to the invention, comprising:
a radio frequency power detector for measuring the actual transmission power, and
an updating module configured to update an expected transmission power value stored in the memory according to the measured transmission power and the current gain setting value,
   improves the accuracy of the established transmission power value.

The radiotelecommunication device according to the invention, comprising a setting module to tune the gain of the amplifier only in response to a power control command from a base station, eases the meeting of the first tolerance on the transmission power changes.

The radiotelecommunication device according to the invention for use in a radio system in which the power control command specifies a step size to increase or decrease the current transmission power of the device, wherein the setting module is adapted to increase or decrease the current gain by the received step size, provides facilities for the gain control.

The radiotelecommunication device according to the invention, wherein the setting module is adapted to select the value of an upper or lower gain setting limit not to be exceeded, according to the at least one measured condition, promotes conformity with standards like UMTS.

The radiotelecommunication device according to the invention, wherein the capturing unit comprises at least:
one sensor chosen from a group including a temperature sensor sensitive to the amplifier temperature,
a voltage sensor sensitive to the power voltage of the amplifier,
and a frequency sensor sensitive to the operating frequency of the amplifier,
   allows more accurate transmission power values to be established.

The invention also relates to a method of determining the current value of the transmission power of a radio telecommunication device as mentioned above, and a recording medium comprising instructions to carry out the claimed method.

These and other aspects of the invention will be apparent from the following description, drawings, and claims.

### BRIEF DESCRIPTION OF THE DRAWINGS

FIG. 1 is a schematic diagram of a radio telecommunication network system;

FIG. 2 is a table used by the system of FIG. 1 to establish a power transmission value; and

FIG. 3 is a flowchart of a method for determining a power transmission value in the system of FIG. 1.

### DESCRIPTION OF PREFERRED EMBODIMENTS

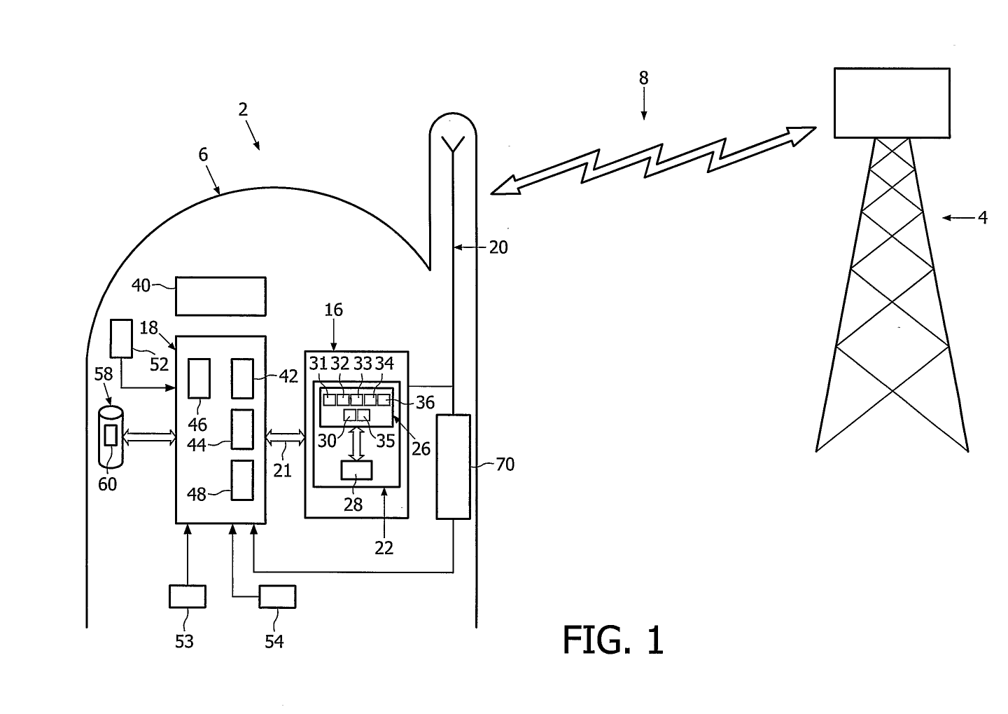

FIG. 1 shows a CDMA radio-telephone system 2, comprising a network base station 4 and a radio telecommunication device. For the purpose of illustration, this radio telecommunication device is a UMTS cellular mobile phone 6. Phone 6 is able to communicate with base station 4 using radio signals 8. To do so, phone 6 implements a CDMA technique.

Base station 4 includes a transmitter and a receiver to send and receive radio signals 8 to and from phone 6.

Phone 6 comprises a radio frequency transceiver 16 and a baseband processor 18 to receive or transmit radio signals 8.

Transceiver 16 is connected to an antenna 20 to receive or transmit radio signals 8.

Transceiver 16 converts a received radio signal into a baseband signal and vice versa. In other words, the main task of transceiver 16 is to remove a carrier from the radio signal or to add such a carrier to a baseband signal. Baseband signals are exchanged between processor 18 and subsystem 16 through a line 21 connecting transceiver 16 to processor 18.

Transceiver 16 is also adapted to set the transmission power of the transmitted radio frequency signals. More precisely, transceiver 16 comprises an amplifier 22 having a tunable gain to set the transmission power. For example, amplifier 22 comprises a bank of attenuators 26 and a programmable switch 28 for selecting the combination of attenuators to obtain a particular gain. Switch 28 operates in response to a gain setting value. The number of attenuators determines the gain setting resolution. In this embodiment, a total of 74×1 dB attenuation steps are required. This can be achieved by using seven attenuators 30 to 36 with attenuation values of 1, 2, 4, 8, 16, 32 and 64 dB, respectively.

Phone 6 includes a power supply unit 40 such as a rechargeable battery to power every component of phone 6.

System 2 is designed to comply with the UMTS standard. As a result, system 2 implements an “inner loop” power control system. The quality of the signals received by base station 4 from phone 6 is measured, and base station 4 sends power control commands at frequent intervals over a downlink communication channel. These commands request phone 6 to increase, maintain or decrease its transmission power. The size of the increase or decrease, called “step” hereinafter, is an integer number of an increment. Here the increment is equal to 1 dB. The first tolerance introduced at the beginning of the description is a tolerance on the transmission power changes in response to one of these commands. The first tolerance is specified according to the step size. For example, if a +1 dB step is requested, the change in the transmission power must be in the range of +0.5 dB to +1.5 dB.

The transmission power of phone 6 must also remain between the maximum and minimum transmission power limits. The maximum transmission power limit is imposed by the UMTS standard. The transmission power of phone 6 must meet the second tolerance introduced at the beginning of the description.

Another requirement of the UMTS standard is that phone 6 should be capable of measuring the transmission power at a specified instant in time and reporting it to base station 4. The accuracy of this measurement is also specified in the UMTS standard depending on the absolute value of the transmission power, with higher accuracy requirements when the transmission power is close to the maximum transmission power limit.

Processor 18 includes a reporting module 42 and a setting module 44 to satisfy the UMTS requirements. In this embodiment, processor 18 also includes a determining module 46 and an updating module 48.

Module 46 is intended to establish the current power transmission value according to the current gain setting value and at least one operating condition of amplifier 22. Here, phone 6 has a data capturing unit to acquire the operating conditions of amplifier 22 which modifies the value of the transmission power corresponding to a given gain setting value. More precisely, the capturing unit comprises, for example:
a voltage sensor 52 to measure the power supply voltage of unit 40,
a temperature sensor 53 sensitive to the operating temperature of amplifier 22, and
a frequency sensor 54 sensitive to the operating frequency of the signal amplified by amplifier 22.

Module 46 is also connected to a storage medium like a memory 58 storing a setting table 60.

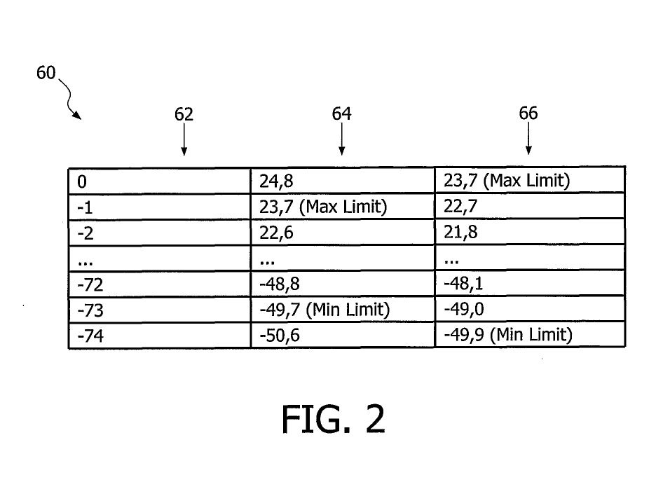

An example of table 60 is illustrated in more detail in FIG. 2. Table 60 comprises a first column 62 having fixed gain setting values expressed as integer attenuation values ranging from 0 dB to −74 dB. In fact, having only integer attenuation values simplifies the design of amplifier 22 because the number of attenuators required to achieve all the gain setting values of table 60 is limited. The values of column 62 form an arithmetic progression, the common difference of which is equal to the increment used in system 2, i.e., “1”.

Table 60 also comprises a second column 64 and a third column 66. Column 64 comprises an expected transmission power value associated with each gain setting value of column 62 under a first set of amplifier operating conditions. For example, the first set of operating conditions corresponds to a measured temperature ranging from 15° C. to 35° C., a measured power voltage ranging from 2.5 V to 3 V and a measured frequency ranging from 1920 to 1950 MHz.

Column 66 comprises a transmission power value associated with each of the gain setting value of column 62 and which corresponds to the transmission power value expected under a second set of amplifier operating conditions. For example, the second set of operating conditions corresponds to a measured temperature ranging from −5° C. to 15° C., a measured power supply voltage ranging from 1.8 V to 2.5 V and a measured frequency ranging from 1950 to 1980 MHz.

The transmission power values of columns 64 and 66 can have as small a resolution as desired. For example, the resolution is stated to one decimal place.

In FIG. 2, only the three first and three last values of each column are represented. The transmission power values of table 60 are expressed in dBm.

Reporting module 42 is designed to send the transmission power value established by module 46 to base station 4 through transceiver 16 and antenna 20.

Setting module 44 tunes the gain of amplifier 22 in response to a received power control command. More precisely, module 44 sends a gain setting value to switch 28 to control amplifier 22.

Finally, updating module 48 is adapted to update the expected transmission power values of columns 64 and 66. To this end, module 48 is connected to a radio frequency transmission power detector 70. Detector 70 is able to measure the actual transmission power of the signal transmitted through antenna 20.

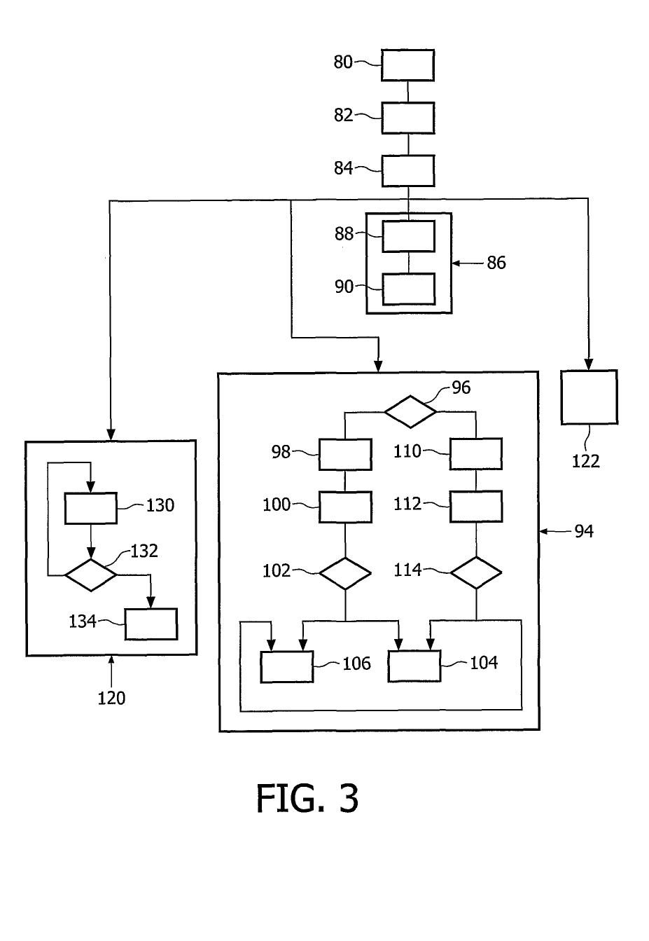

In this embodiment, processor 18 is a programmable calculator and memory 58 comprises instructions to carry out the method of FIG. 3 when these instructions are executed by processor 18.

The operation of system 2 will now be explained with reference to FIG. 3.

Initially, in step 80, a calibration of phone 6 is carried out to measure each of the transmission power values of table 60. These measures are carried out by fixing a given gain setting value, adjusting given operating conditions for amplifier 22 and then measuring the transmission power resulting from the given gain setting value and operating conditions.

In step 82, once every transmission power value has been measured, they are stored in table 60 in memory 58. Subsequently, phone 6 may be used.

During the operation of phone 6, in step 84, sensors 52 to 54 measure the operating conditions of phone 6, which influences the actual transmission power of phone 6 corresponding to a given gain setting value. Here, the temperature, the operating frequency, and the power voltage of amplifier 22 are measured.

Thereafter, in step 86, module 46 establishes the current transmission power value without measuring the transmission power. In particular, during an operation 88, module 46 selects the column of table 60 corresponding to the measured operating condition. Assuming that column 64 is selected during operation 88, in an operation 90, module 46 selects the transmission power value associated with the current gain setting value in the selected column. For example, if the current gain setting value is −2 dB, the established transmission power value is 22.6 dBm.

In parallel to step 86, in step 94, module 44 tunes the gain of amplifier 22 only in response to a received power control command. More precisely, in an operation 96, module 44 receives the power control command sent by base station 4 and determines if the transmission power should be increased, maintained or decreased in response to the received command.

If base station 4 increases the transmission power, during an operation 98, module 44 raises the current gain setting value to increase the amplifier gain by the received number of increments. For example, if a +1 dB step is requested, the current gain setting value is incremented by 1 dB. Then, during an operation 100, module 44 selects an upper gain setting limit not to be exceeded pursuant to the measured conditions. To this end, module 44 uses the column of table 60 which was selected during operation 88 and selects the gain setting value associated with the expected transmission power value which is just below the maximum transmission power limit in column 64. Here “−1 dB” is selected as the upper gain setting limit.

Once the upper gain setting limit has been selected, during an operation 102, module 44 checks whether the new gain setting value established during operation 98 is smaller or equal to the selected upper gain setting limit.

If the new gain setting value is smaller than or equal to the selected upper gain setting limit, module 44 proceeds to an operation 104 during which it controls programmable switch 28 to set the new gain in amplifier 22. On the other hand, if the new gain setting value exceeds the selected upper gain setting limit, module 44 proceeds to an operation 106 during which it controls programmable switch 28 to maintain or to set a gain corresponding to the upper gain setting limit. After operation 104 or 106, the process returns to step 84. By doing so, phone 6 complies with the second tolerance on the maximum transmission power limit.

If during operation 96, module 44 determines that the base station commands a decrease in the transmission power, then the method proceeds to an operation 110. During operation 110, module 44 decreases the current gain setting value by the received number of increment and then proceeds to an operation 112. During operation 112, module 44 selects a lower gain setting limit according to the measured operating conditions of amplifier 22. Operation 112 is similar to operation 100 with the exception that module 44 selects the gain setting value of column 62 associated with the expected transmission power value of column 64 which is just above the minimum transmission power limit. Thus, in this example, module 44 selects the value −73 dB.

In an operation 114, module 44 checks if the new gain setting value is higher than or equal to the selected lower gain setting limit. If the new gain getting value is higher, module 44 proceeds to operation 104 and if otherwise, module 44 proceeds to operation 106.

If during operation 96, module 44 determines that the transmission power is to be maintained, the process stops and returns to step 84.

Still in parallel to steps 86 and 94, an updating step 120 and a reporting step 122 may be carried out.

In a step 120, module 48 updates, if necessary, all the transmission power value of one column of table 60. First, during an operation 130, detector 70 measures the actual transmission power value and sends the measured value to module 48. Then, during an operation 132, module 48 compares the measured transmission power value to the expected value read from table 60 during step 86. If the difference between the measured transmission power value and the expected value is significant, then, during an operation 134, the difference between the measured transmission power value and the expected value is applied to all the values in the table column selected in step 86. As a result, the gain setting value which corresponds to the upper limit may change, since the limit is defined by the UMTS standard in absolute power terms. For example, if an error of 1 dB is detected between the expected power value and the measured power, all the expected power values are adjusted by 1 dB. This means that the gain setting corresponding to the upper limit now generates an absolute power 1 dB over the limit set by the UMTS standard. Hence the next gain setting lower in the table should be designated as the upper limit during operation 100.

The difference is determined to be significant if the difference is greater than a predetermined threshold, for example. If during operation 132, the difference is not significant, module 48 does not update any expected transmission power values.

Finally, in step 122, the expected transmission power value determined in step 86 is transmitted to base station 4 at specified instants in time to satisfy the UMTS standard.

In the above embodiment, the value of the transmission power is determined with a high accuracy in step 86 because the operating conditions of amplifier 22 are taken into consideration. Thus, the tolerance of the UMTS standard is met without necessarily requiring a measuring of the actual transmission power.

The accuracy of the transmission power value determined in step 86 depends on the accuracy of the transmission power value stored in table 60. As the phone 6 is under lasting wear and tear from normal usage, the values of table 60 may require to be updated from time to time. Module 48 automatically updates table 60 and so automatically compensates for the effects of the aging of phone 6.

In phone 6, only module 44 tunes the gain of amplifier 22. This reliably tunes amplifier 22 while meeting the requirements of standards like UMTS. In fact, other possible methods compensate for changes in the operating conditions of amplifier 22 by directly tuning the gain to maintain the transmission power constant even if the operating conditions change. With such methods it is difficult to satisfy industry standards because if the gain is simultaneously changed in response to a power control command and a change in the measured operating conditions, the result is a transmission power change which is out of tolerance.

Many additional embodiments are possible. For example, updating module 48 and detector 70 may be omitted if automatic updating of table 60 is not required.

The capturing unit has been described in the particular case where it comprises three sensors 52 to 54. However, in other embodiments, the capturing unit includes one, two or three sensors chosen from a group having sensor 52, sensor 53 and sensor 54. In another embodiment, an aging sensor is added to the previous group of sensors. Still in another embodiment, sensor 54 is replaced by a module that reads the operating frequency from data received from the base station. In fact, in a UMTS network the operating frequency is set by the network and signalled to the radio telecommunication device.

The gain control of amplifier 22 has been described with a programmable switch and a bank of attenuators. Other gain controls may be used. For example, in another embodiment, module 44 uses a digital-to-analog converter to generate a voltage level which is used to control the gain of an amplifier or an attenuator. In such an embodiment, the number of digital bits supported by the converter fixes the gain setting resolution. Thus, in such an embodiment, integer gain setting values like the one in column 62 are preferable to simplify the design of the telecommunication device.

The number of columns of table 60 may be increased to contain further transmission power values corresponding to other sets of operating conditions of amplifier 22. Moreover, table 60 can be replaced with a mathematical function giving the expected transmission power value according to the current gain setting value and the measured operating conditions.

The above embodiment has been described in the particular case of the UMTS standard. However, establishing the transmission power value without needing a radio frequency power detector may be applied with other standards as well.

1. A radio telecommunication device comprising:
an amplifier having a tunable gain for setting a transmission power of a radio communication according to a gain setting value
wherein the telecommunication device comprises:
a capturing unit to measureacquire at least one operating condition of the amplifier influencing the value of the transmission power corresponding to a given gain setting value, and
a determining module adapted to establish the current value of the transmission power from the current gain setting value of the amplifier and the at least one measured operating condition.

2. The device of claim 1, wherein:
the device comprises a memory storing gain setting values and a first and a second expected transmission power vales associated to each stored gain setting values, and
the determining module is adapted to select either one of the first and second expected transmission power values according to the at least one measured condition to establish the current value of the transmission power.

3. The device of claim 2, wherein each stored gain setting value is an integer value.

4. The device according to claim 2, wherein the device comprises:
a radio frequency power detector for measuring the actual transmission power, and
an updating module configured to update an expected transmission power value stored in the memory according to the measured transmission power and the current gain setting value.

5. The device according to claim 1, wherein the device comprises a setting module to tune the gain of the amplifier only in response to a power control command of a base station.

6. The device of claim 5 for use in a radio system in which the power control command specifies a step size to increase or decrease the current transmission power of the device, wherein the setting module is adapted to increase or decrease the current gain by the received step size.

7. The device according to claim 5, wherein the setting module is adapted to select the value of an upper or lower gain setting limit not to be exceeded, according to the at least one measured condition.

8. The device according to claim 1, wherein the capturing unit comprises at least one sensor chosen from a group including a temperature sensor sensitive to the amplifier temperature, a voltage sensor sensitive to the power voltage of the amplifier, and a frequency sensor sensitive to the operating frequency of the amplifier.

9. The device according to claim 1, wherein the device is a mobile phone.

10. A method of determining the current value of a transmission power of a radio telecommunication device, the radio telecommunication device comprising an amplifier having a tunable gain to set the transmission power of a radio communication according to a gain setting value, wherein the method comprises:
a step of measuring at least one operating condition of the amplifier that may influence the value of the transmission power corresponding to a given gain setting value, and
a step of establishing the current value of the transmission power from the current gain setting value of the amplifier and the at least one measured operating condition.

11. The method of claim 10, further comprising a step of storing gain setting values and a first and a second expected transmission power values associated to each stored gain setting values in a memory, and wherein the step of establishing step comprises the operation of selecting either one of the first and second expected transmission power values according to the at least one measured condition to establish the current value of the transmission power.

12. The method of claim 11, further comprising a step of updating an expected transmission power value stored in the memory according to a measured transmission power and the current gain setting value.

13. The method according to claim 10, further comprising the step of tuning the gain of the amplifier solely in response to a power control command of a base station.

14. The method of claim 13 for a telecommunication device which receives power control commands specifying a step size to increase or decrease the current transmission power, wherein the tuning step comprises the operation of increasing or decreasing the current gain by the received step size.

15. The method according to claim 10, further comprising the step of selecting the value of an upper or lower gain setting limit not to be exceeded according to the at least one measured condition.

16. The method according to claim 10, further comprising the step of sending the value of the established transmission power to a base station.

17. A recording medium comprising instructions to execute a method of determining the current value of a transmission power according to claim 10, when these instructions are executed by a processor.
